(19) United States
(12) Patent Application Publication
(10) Pub. No.: US 2006/0220170 A1
(43) Pub. Date: Oct. 5, 2006

(54) High-voltage field effect transistor having isolation structure

(76) Inventors: Chih-Feng Huang, Jhubei City (TW); Tuo-Hsin Chien, Tucheng City (TW); Jenn-yu G. Lin, Taipei (TW); Ta-yung Yang, Milpitas, CA (US)

Correspondence Address: J C PATENTS, INC., 4 VENTURE, SUITE 250, IRVINE, CA, 92618, US

(21) Appl. No.: 11/096,959

(22) Filed: Mar. 31, 2005

(51) Int. Cl. H01L 29/00

(52) U.S. Cl. 257/500

(57) ABSTRACT

A high-voltage MOSFET having isolation structure is provided. An N-type MOSFET includes a first deep N-type well. A first P-type region is formed in the first deep N-type well to enclose a first source region and a first contact region. A first drain region is formed in the first deep N-type well. A P-type MOSFET includes a second deep N-type well. A second P-type region is formed in the second deep N-type well to enclose a second drain region. A second source region and a second contact region are formed in the second deep N-type well. A polysilicon gate oxidation layer is disposed above the thin gate oxidation layer and the thick field oxidation layer to control the current in the channel of the MOSFET. Separated P-type regions provide further isolation between MOSFETs. A first gap and a second gap increase the breakdown voltage of the high-voltage MOSFET.

### BACKGROUND OF THE INVENTION

1. Field of the Invention

The present invention relates to a semiconductor device. More particularly, the present invention relates to a metal oxide semiconductor field effect transistor (MOSFET).

2. Description of the Related Art

To integrate control circuits and high-voltage transistors has become a development trend for present power integrated circuit (Power IC). Therefore, if high-voltage transistor devices can be fabricated using standard process, it would be a preferable way for integrating a monolithic IC. However, the high-voltage transistor fabricated in current standard process does not have an isolation structure, and the transistor current without isolation structure may flow in the substrate and cause disturbance to the control circuit. Also, the transistor current may produce ground bounce to affect the control signal of the control circuit. Accordingly, the transistor without the isolation structure is not suitable for the integrated technology. In a conventional technology, a thin epitaxial layer and an N-type buried layer are used to provide the transistor an isolation structure and high breakdown voltage, but the complicated manufacturing process increases the fabricating cost and reduces the yield.

### SUMMARY OF THE INVENTION

Accordingly, to overcome the above disadvantages, the present invention provides a field effect transistor device having higher breakdown voltage, lower conductive resistance and an isolation structure for integrating a monolithic IC.

The present invention provides a high-voltage MOSFET having an isolation structure, and the field effect transistor device includes an N-type MOSFET and a P-type MOSFET disposed in a P-type substrate.

The N-type MOSFET comprises a first N-type diffusion region having N-type conductive ions to form a first deep N-type well in a P-type substrate; a first P-type diffusion region having P-type conductive ions to form a P-type region in the first deep N-type well; a first drain diffusion region having N+-type conductive ions to form a first drain region in the first N-type diffusion region; a first source diffusion region having N+-type conductive ions to form a first source region; and a first contact diffusion region having P+-type conductive ions to form a first contact region, wherein the first P-type diffusion region encloses the first source region and the first contact region.

The P-type MOSFET comprises a second N-type diffusion region having N-type conductive ions to form a second deep N-type well in the P-type substrate; a second P-type diffusion region having P-type conductive ions to form a second P-type region in the second deep N-type well; a second drain diffusion region having P+-type conductive ions to form a second drain region in the second N-type diffusion region; a second source diffusion region having P+-type conductive ions to form a second source region; and a second contact diffusion region having N+-type conductive ions to form a second contact region, wherein the second N-type diffusion region encloses the second source region and the second contact region.

A plurality of separation P-type diffusion regions having P-type conductive ions form a plurality of separated P-type regions in the P-type substrate to provide further isolation between MOSFETs. The first P-type region located in the first N-type diffusion region, the second P-type region located in the second N-type diffusion region, the plurality of separated P-type regions, the first deep N-type well and the second deep N-type well form the depletion regions.

A first channel is formed between the first source region and the first drain region. A second channel is formed between the second source region and the second drain region. A first polysilicon gate is located on a first thin gate oxidation layer and a first thick field oxidation layer to control a first current flow in the first channel. A second polysilicon gate is located on a second thin gate oxidation layer and a second thick field oxidation layer to control a second current flow in the second channel.

Furthermore, the first deep N-type well and the second deep N-type well respectively formed by the first N-type diffusion region and the second diffusion region provide a low-resistance path which limits the transistor current between the drain region and the source region.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a diagram showing an N-type MOSFET.

FIG. 1B is a diagram showing a P-type MOSFET.

FIG. 2A is a top view showing a conventional high-voltage transistor device.

FIG. 2B is a top view showing a high-voltage transistor device of the present invention.

FIG. 3A is a side view showing the conventional high-voltage transistor device.

FIG. 3B is a side-view showing the high-voltage transistor device of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

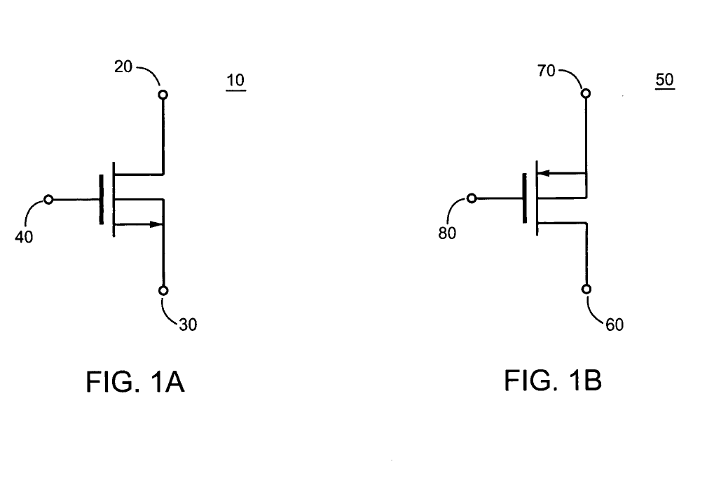

FIG. 1A is a diagram showing an N-type MOSFET 10, comprising a drain 20, a source 30, and a polysilicon gate 40. FIG. 1B is a diagram showing a P-type MOSFET 50, comprising a drain 60, a source 70 and a polysilicon gate 80.

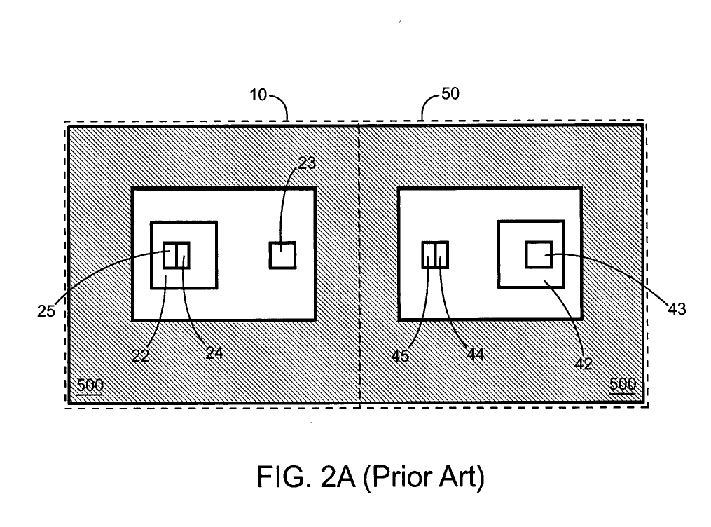

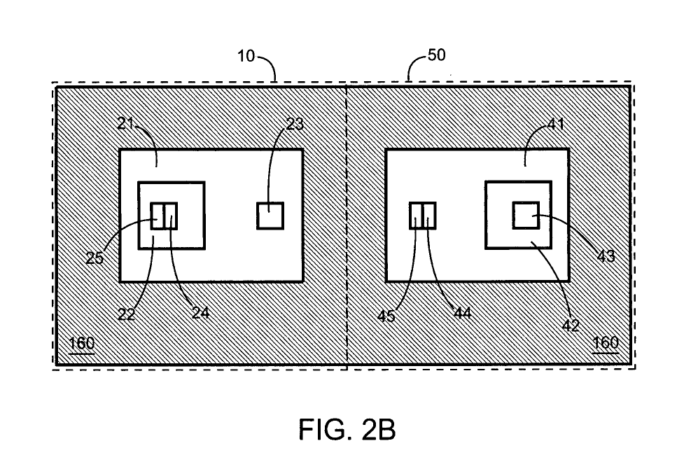

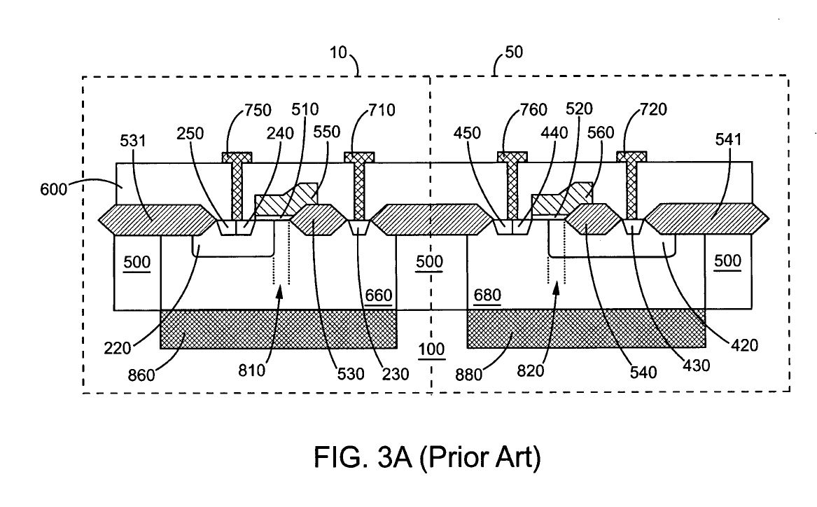

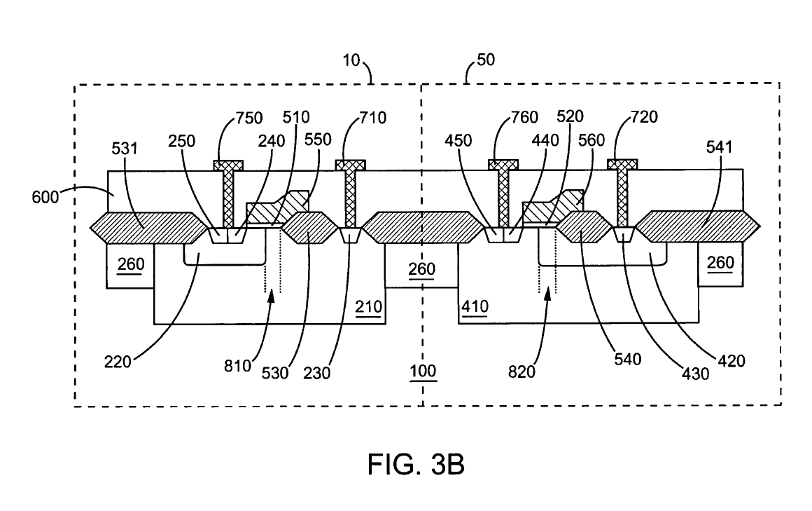

FIG. 2A is a top view showing a conventional high-voltage transistor device, comprising an N-type MOSFET 10 and a P-type MOSFET 50. FIG. 3A is a side view showing a conventional high-voltage transistor device having an isolation structure. As shown in FIG. 2A and FIG. 3A, the N-type MOSFET 10 and P-type MOSFET 50 include a P-type substrate 100, an N+-type buried layer 860 and a P+-type buried layer 880 formed in the P-type substrate 100, an N-type epitaxial layer 660 and an N-type epitaxial layer 680 respectively formed on the N+-type buried layer 860 and the P+-type buried layer 880, a plurality of separation P+-type region 500 having P+-type ions formed in the N-type epitaxial layers 660 and 680 to provide isolation between MOSFETs.

FIG. 2B and FIG. 3B are respectively a top view and a side view showing a high-voltage transistor device of the present invention. As shown in FIG. 2B and FIG. 3B, an N-type MOSFET 10 includes P-type substrate 100. A first N-type diffusion region 21 having N-type conductive ions forms a first deep N-type well 210 in the P-type substrate 100. A first P-type diffusion region 22 having P-type conductive ions forms a first P-type region 220 in the first deep N-type well 210. A first drain diffusion region 23 having N+-type conductive ions forms a first drain region 230 in the first N-type diffusion region 21. A first source diffusion region 24 having N+-type conductive ions forms a first source region 240. A first channel is formed between the first source region 240 and the first drain region 230. A first contact diffusion region 25 having P+-type conductive ions forms a first contact region 250, wherein the first P-type diffusion region 22 encloses the first source region 240 and the first contact region 250. The N-type MOSFET 10 further includes a plurality of separated P-type diffusion regions 160 having P-type conductive ions, and a plurality of separated P-type regions 260 formed in the P-type substrate 100 to provide isolation between MOSFETs.

The P-type MOSFET 50 also includes the P-type substrate 100, a second N-type diffusion region 41 to form a second deep N-type well 410 in the P-type substrate 100. A second P-type diffusion region 42 having P-type conductive ions forms a second P-type region 420 in the second deep N-type well 410. A second drain diffusion region 43 having P+-type conductive ions forms a second drain region 430 in the second P-type diffusion region 42. A second source diffusion region 44 having P+-type conductive ions forms a second source region 440. A second-channel is formed between the second source region 440 and the second drain region 430. A second contact diffusion region 45 having N+-type conductive ions forms a second contact region 450, wherein the second N-type diffusion region 41 encloses the second source region 440 and the second contact region 450. The P-type MOSFET 50 further includes the plurality of separated P-type diffusion regions 160, and the separated P-type region 260 formed in the P-type substrate 100 to provide isolation between MOSFETs.

The fabricating process of the first P-type region 220 and the second P-type region 420 may be a P-type well process or a P-type body process. A first thin gate oxidation layer 510 and a second thin gate oxidation layer 520, a first thick field oxidation layer 530, a second thick field oxidation layer 540, a third thick field oxidation layer 531 and a fourth thick field oxidation layer 541 are formed on the P-type substrate 100. The first polysilicon gate 550 is located on the first thin gate oxidation layer 510 and the first field oxidation layer 530 to control the current flow of the first channel of the N-type MOSFET 10. A second polysilicon gate 560 is located on the second thin gate oxidation layer 520 and the second field oxidation layer 540 to control the current flow of the second channel of the P-type MOSFET 50. A silicon oxidation isolation layer 600 covers the polysilicon gates 550 and 560 and thick field oxidation layers 530, 531, 540 and 541. A first drain metal contact 710 and a second drain metal contact 720 having metal electrodes connect with the first drain diffusion region 23 and the second drain diffusion region 43, respectively. A first source metal contact 750 having a metal electrode connects with the first source diffusion region 24 and the first contact diffusion region 25. A second source metal contact 760 having another metal electrode connects with the second source diffusion region 44 and the second contact diffusion region 45.

A first gap 810 is used to maintain a space between the first thick field oxidation layer 530 and the first P-type region 220 to increase the breakdown voltage of the N-type MOSFET 10. A second gap 820 is used to maintain another space between the second thick field oxidation layer 540 and the second deep N-type well 410 to increase the breakdown voltage of the P-type MOSFET 50. The first P-type region 220, the second P-type region 420, the separated P-type region 260, the first deep N-type well 210 and the second deep N-type well 410 form a depletion region to provide isolation between MOSFETs. The first P-type region 220 and the first deep N-type well 210 form a depletion region, and the second P-type region 420 and the second deep N-type well 410 form another depletion region. Along with the P-type region 260, the isolation effect between transistors is more preferable.

Only through a simplified process, the high-voltage transistor device of the present invention, such as the N-type MOSFET 10 and the P-type MOSFET 50, has increased breakdown voltage, lower conductive resistance, and isolation structure. In addition, the conventional high-voltage transistor isolation structure uses the N-type epitaxial layer 660 to enclose the first drain region 230 and the first P-type region 220 of the N-type MOSFET 10, and uses the N-type epitaxial layer 680 to enclose the second source region 440, the second contact region 450 and the second P-type region 420 of the P-type MOSFET 50. The present invention applies the first deep N-type well 210 and the second deep N-type well 410 to do the same. Therefore, the present invention does not require additional masks for fabricating epitaxial layers, such as the N-type epitaxial layers 660 and 680, in the conventional process. The present invention only uses a standard well structure to fabricate the transistor structure with lower cost, high yield and isolation structure.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A high-voltage N-type MOSFET, comprising:
a P-type substrate;
a first N-type diffusion region, having N-type conductive ions to form a first deep N-type well in said P-type substrate;
a first P-type diffusion region, having P-type conductive ions to form a first P-type region in said first deep N-type well;
a first drain diffusion region, having N+-type conductive ions to form a first drain region in said first N-type diffusion region;
a first source diffusion region, having N+-type conductive ions to form a first source region, wherein a first channel is formed between said first source region and said first drain region;
a first contact diffusion region, having P+-type conductive ions to form a first contact region, wherein said first P-type region encloses said first source region and said first contact region;
a plurality of separated P-type diffusion regions, having P-type conductive ions to form a plurality of P-type separated regions in said P-type substrate to provide isolation;
a first thin gate oxidation layer and a first thick field oxidation layer, formed on said P-type substrate;
a first polysilicon gate, located on said first thin gate oxidation layer and said first thick field oxidation layer to control a current flow in said first channel;
a silicon oxide isolation layer, covering said first polysilicon gate and said first thick field oxidation layer;
a first drain metal contact, having a first metal electrode, connected with said first drain diffusion region;
a first source metal contact, having a second metal electrode, connected with said first contact diffusion region and said first source diffusion region; and
a first gap between said first thick field oxidation layer and said first P-type region, maintaining a space for increasing a breakdown voltage of said high-voltage N-type MOSFET.

2. The high voltage N-type MOSFET according to claim 1, wherein said first P-type region in said first deep N-type well is fabricated in a P-type well process.

3. The high-voltage N-type MOSFET according to claim 1, wherein said first P-type region in said first deep N-type well is fabricated in a P-type body process.

4. A high-voltage P-type MOSFET, comprising:
a P-type substrate;
a second N-type diffusion region, having N-type conductive ions to form a second deep N-type well in said P-type substrate;
a second P-type diffusion region, having P-type conductive ions to form a second P-type region in said second deep N-type well;
a second drain diffusion region, having P+-type conductive ions to form a second drain region in said second P-type diffusion region;
a second source diffusion region, having P+-type conductive ions to form a second source region, wherein a second channel is formed between said second source region and said second drain region;
a second contact diffusion region, having N+-type conductive ions to form a second contact region, wherein said second N-type diffusion region encloses said second source region and said second contact region;
a plurality of separated P-type diffusion regions, having P-type conductive ions to form a plurality of P-type separated regions in said P-type substrate to provide isolation;
a second thin gate oxidation layer and a second thick field oxidation layer, formed on said P-type substrate;
a second polysilicon gate located on said second thin gate oxidation layer and said second thick field oxidation layer to control a current flow in said second channel;
a silicon oxidation isolation layer, covering said second polysilicon gate and said second thick field oxidation layer;
a second drain metal contact, having a third metal electrode connected with said second drain diffusion region;
a second source metal contact, having a fourth metal electrode connected with said second contact diffusion region and said second source diffusion region; and
a second gap between said second thick field oxidation layer and said second deep N-type well, maintaining a space for increasing a breakdown voltage of said high-voltage P-type MOSFET.

5. The high-voltage P-type MOSFET according to claim 4, wherein said second P-type region in said second deep N-type well is fabricated in a P-type well process.

6. The high-voltage P-type MOSFET according to claim 4, wherein said second P-type region in said second deep N-type well is fabricated in a P-type body process.
